(19) United States
(12) Patent Application Publication
(10) Pub. No.: US 2016/0126199 A1
(43) Pub. Date: May 5, 2016

(54) SIGNAL PATHS FOR RADIO-FREQUENCY MODULES

(71) Applicant: SKYWORKS SOLUTIONS, INC., Woburn, MA (US)

(72) Inventors: Ambarish ROY, Waltham, MA (US); Guillaume Alexandre BLIN, Carlisle, MA (US)

(21) Appl. No.: 14/927,698

(22) Filed: Oct. 30, 2015

Related U.S. Application Data
(60) Provisional application No. 62/073,045, filed on Oct. 31, 2014.

(51) Int. Cl. H01L 23/66; H01L 23/31; H05K 1/18; H04B 1/3827; H05K 1/02; H01L 25/16; H01L 23/64; H01L 23/498; H01P 3/08

(52) U.S. Cl. CPC H01L 23/66; H01L 23/49838; H01L 23/3114; H05K 1/181; H01P 3/08; H05K 1/0224; H01L 25/16; H01L 23/642; H01L 23/49822; H04B 1/3833; H01L 2223/6627; H01L 2223/6672

(57) ABSTRACT

Signal paths for radio-frequency (RF) modules. In some embodiments, an RF module can include a plurality of components configured to facilitate processing of an RF signal, and a packaging substrate on which the plurality of components are mounted. The packaging substrate can have multiple layers and include an RF signal path implemented on a selected layer. Each of at least one neighboring layer above the selected layer and at least one neighboring layer below the selected layer can be configured to be sufficiently free of a ground feature relative to the RF signal path to yield a reduced parasitic capacitance while substantially maintaining a desired impedance for the RF signal path.

### CROSS-REFERENCE TO RELATED APPLICATION(S)

This application claims priority to U.S. Provisional Application No. 62/073,045 filed Oct. 31, 2014, entitled RADIO-FREQUENCY MODULES HAVING IMPROVED SIGNAL PATHS, the disclosure of which is hereby expressly incorporated by reference herein in its respective entirety.

### BACKGROUND

1. Field

The present disclosure relates to signal paths for radio-frequency (RF) modules.

2. Description of the Related Art

Many radio-frequency (RF) modules are implemented as packaged modules. Such an RF module typically includes a packaging substrate such as a laminate substrate. The laminate nature of the packaging substrate can allow various electrically conductive features to be implemented on one or more laminate layers. Such conductive features can include, for example, an RF signal path and a ground plane.

### SUMMARY

In accordance with a number of implementations, the present disclosure relates to a radio-frequency (RF) module that includes a plurality of components configured to facilitate processing of an RF signal, and a packaging substrate on which the plurality of components are mounted. The packaging substrate has multiple layers and includes an RF signal path implemented on a selected layer. Each of at least one neighboring layer above the selected layer and at least one neighboring layer below the selected layer is configured to be sufficiently free of a ground feature relative to the RF signal path to yield a reduced parasitic capacitance while substantially maintaining a desired impedance for the RF signal path.

In some embodiments, the RF module can be a front-end module (FEM). The RF signal can be an amplified transmit (Tx) signal or a received (Rx) signal.

In some embodiments, the packaging substrate can include a laminate substrate. The laminate substrate can include, for example, at least 6 layers.

In some embodiments, each of at least one neighboring layer above the selected layer and at least one neighboring layer below the selected layer can be substantially free of a ground feature that would yield parasitic capacitance with the RF signal path on the selected layer. In some embodiments, each of at least two neighboring layers above the selected layer and at least two neighboring layers below the selected layer can be substantially free of a ground feature that would yield parasitic capacitance with the RF signal path on the selected layer. Each of the at least two neighboring layers above the selected layer and at least two neighboring layers below the selected layer can be substantially free of a ground feature that overlaps with the RF signal path on the selected layer.

In some embodiments, the desired impedance for the RF signal path can include an impedance value in a range of +/−10%, +/−5%, or +/−2% about an ideal impedance value. The ideal impedance value can be, for example, approximately 50 Ohms.

In some embodiments, the plurality of components can include a semiconductor die having an RF integrated circuit (RFIC). The plurality of components can further include a surface-mount technology (SMT) device. In some embodiments, the RF module can further include an overmold implemented over the packaging substrate to substantially encapsulate the plurality of components.

In some implementations, the present disclosure relates to a wireless device that includes a transceiver configured to process a radio-frequency (RF) signal, and an RF module in communication with the transceiver. The RF module includes a plurality of components configured to facilitate processing of the RF signal, and a packaging substrate on which the plurality of components are mounted. The packaging substrate has multiple layers and includes an RF signal path implemented on a selected layer. Each of at least one neighboring layer above the selected layer and at least one neighboring layer below the selected layer is configured to be sufficiently free of a ground feature relative to the RF signal path to yield a reduced parasitic capacitance while substantially maintaining a desired impedance for the RF signal path. The wireless device further includes an antenna in communication with the RF module. The antenna is configured to facilitate transmission and/or reception of the RF signal.

In some embodiments, the wireless device can be, for example, a cellular phone.

According to some teachings, the present disclosure relates to a device for fabrication of packaged radio-frequency (RF) modules. The device includes a substrate panel having an array of units, with each unit configured to be a packaging substrate for an individual packaged RF module. The substrate panel includes multiple layers. The device further includes an RF signal path implemented on a selected layer of each unit of the substrate panel. Each of at least one neighboring layer above the selected layer and at least one neighboring layer below the selected layer is configured to be sufficiently free of a ground feature relative to the RF signal path to yield a reduced parasitic capacitance while substantially maintaining a desired impedance for the RF signal path.

In some embodiments, the substrate panel can include a laminate substrate panel. Each of the at least one neighboring layer above the selected layer and at least one neighboring layer below the selected layer can be substantially free of a ground feature that overlaps with the RF signal path on the selected layer. Each of the selected layer, the at least one neighboring layer above the selected layer and the at least one neighboring layer below the selected layer can include a ground feature that is sufficiently displaced laterally from the RF signal path to contribute at least partially to the maintaining of the desired impedance.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a packaged module having a packaging substrate with a radio-frequency (RF) signal path.

FIG. 2A depicts a transmission line representation of an RF signal path as a simple resistive 50 Ohms trace without parasitic capacitance to ground.

FIG. 2B depicts a representation of an RF signal path as a simple resistive 50 Ohms trace with parasitic capacitance to ground.

FIG. 3 shows examples of insertion loss associated with the RF signal paths of FIGS. 2A and 2B.

FIG. 4 shows that the impedances of the RF signal paths of FIGS. 2A and 2B can generally remain constant for both parasitic and non-parasitic paths.

FIG. 5A depicts a representation of an ideal RF signal path without parasitic capacitance to ground.

FIG. 5B depicts a representation of an ideal RF signal path with parasitic capacitance to ground.

FIG. 6 shows examples of insertion loss associated with the RF signal paths of FIGS. 5A and 5B.

FIG. 7 shows an example configuration that can be implemented to reduce the parasitic capacitance effect associated with an RF signal path.

FIG. 8 shows the insertion loss examples of FIG. 6, as well as for the example configuration of FIG. 7.

FIG. 9 shows an example laminate substrate of a packaged module with 6 layers that can be utilized to accommodate routing designs for RF signal paths for receive (Rx) and/or transmit (Tx) operations.

FIG. 10 shows a closer view of the example of FIG. 9.

FIG. 11A shows a side view of an example laminate substrate that can be utilized as a packaging substrate, where an RF signal path can be implemented relative to one or more grounding features.

FIG. 11B shows a plan view of an example laminate layer having the RF signal path of FIG. 11A.

FIG. 12A shows a side view of another example laminate substrate that can be utilized as a packaging substrate, where an RF signal path can be implemented relative to one or more grounding features.

FIG. 12B shows a plan view of an example laminate layer having the RF signal path of FIG. 12A.

FIG. 13 depicts a packaging substrate having one or more features as described herein.

FIG. 14 depicts a packaged module having one or more features as described herein.

FIG. 15 shows a process that can be implemented to fabricate a packaging substrate having one or more features as described herein.

FIG. 16 shows a process that can be implemented to fabricate a packaged module having one or more features as described herein.

FIG. 17 depicts an example wireless device having one or more features as described herein.

### DETAILED DESCRIPTION OF SOME EMBODIMENTS

The headings provided herein, if any, are for convenience only and do not necessarily affect the scope or meaning of the claimed invention.

Effective routing of radio-frequency (RF) signals in RF modules are important for integrating active and/or passive devices for a number of applications such as front-end filtering. Routing losses due to parasitics can typically add insertion loss to 50 or non-50 Ohms paths. Losses typically increase at higher frequencies and may have 20-40% of signal loss. In many applications, 50 Ohms routing parasitics are neglected as they are tough to account for.

In RF front-end applications, receive (Rx) paths can include low noise amplifiers (LNAs) whose inputs, incorporating related routings, preferably have high Q and low loss. Transmit (Tx) paths can include active or passive devices which can be lossy throughout from Tx chain to an antenna.

Disclosed herein are devices and methods related to techniques that can limit parasitic effects to ground to, for example, reduce insertion loss in Rx and/or Tx paths from/to an antenna. In some embodiments, such techniques can be implemented in 2-layer, 4-layer, 6-layer and higher layers packaging substrates such as laminate substrates for RF modules. It will be understood that one or more features of the present disclosure can also be implemented in laminate substrates having other numbers of layers. It will also be understood that one or more features of the present disclosure can also be implemented in other types of packaging substrates, including, for example, ceramic substrates.

In some signal routing configurations, routing lines can be made to be more inductive to compensate for capacitance at higher frequencies. Such an approach typically involves reducing the line width and increasing the line length of the routing traces. However, such an approach of increasing the inductance also yields higher losses due to increase in resistance.

It is noted that routing losses are typically dominant or greater at locations where ground layers or features are aligned next to an RF signal path (Rx and Tx). Accordingly, and as described herein, careful design of the ground around the Rx and Tx signal paths can yield very low parasitic to ground while maintaining a desired level of impedance of the RF path (e.g., to or from active or passive devices). As also described herein, resistance of an RF path does not necessarily need to increase to reduce the parasitic effect.

It is noted that a given a signal routing path has resistive losses which generally cannot be removed. It can be 50 Ohms or non-50 Ohms depending on the design. Along with the routing resistance, there can be parasitic inductance and/or capacitance around the signal routing path. In many situations, parasitic capacitance can be mostly capacitance to ground along the signal routing path. Grounding around the signal routing path is typically utilized due to less coupling to other RF routing paths, but the cost typically involves the foregoing parasitic capacitance to ground.

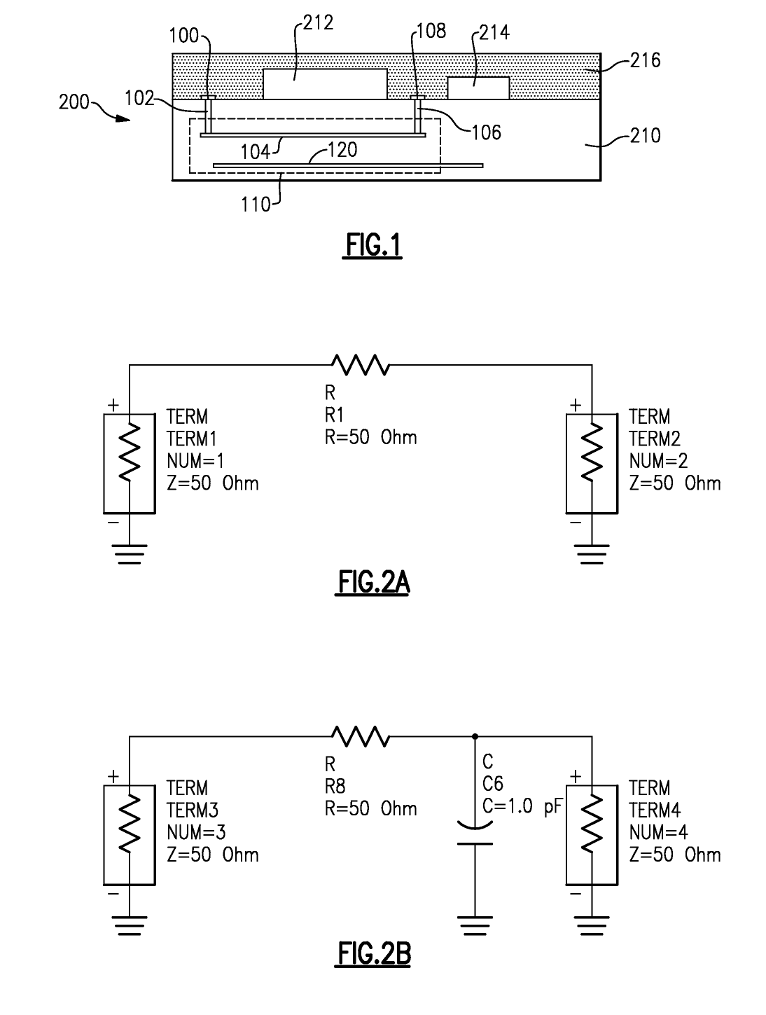

FIG. 1 shows an example RF module 200 having a signal routing path 104 implemented within a packaging substrate 210 such as a laminate substrate. In the example shown, the signal routing path 104 can provide routing for an RF signal between terminals 100 and 108, through a conductive feature 102 such as a conductive via, the signal routing path 104, and a conductive feature 106 such as a conductive via.

In the example of FIG. 1, a ground plane 120 is shown to be implemented within the packaging substrate 210. Such a ground plane can be positioned relative to the signal routing path 104 so as to provide, for example, a desired impedance of the signal routing path 104 for an RF signal being routed. Accordingly, an assembly of the signal routing path 104 and one or more ground planes can be characterized as a transmission line 110. Examples related to such transmission line characterization are described herein in greater detail.

In the example RF module 200 of FIG. 1, the terminals 100, 108 associated with the signal routing path 104 can be coupled to respective RF related circuits, passive devices, other routing paths, etc. so as to allow processing of RF signals by the RF module 200. Such RF related circuits can include, for example, one or more RF integrated circuits (RFICs) 212 (e.g., in a semiconductor die format), and such passive devices can include, for example, surface-mount technology (SMT) devices such as capacitors, inductors, resistors, etc. In the example of FIG. 1, the RF module 200 is shown to include an overmold 216 formed over the packaging substrate 210 so as to generally encapsulate the components mounted on the packaging substrate 210.

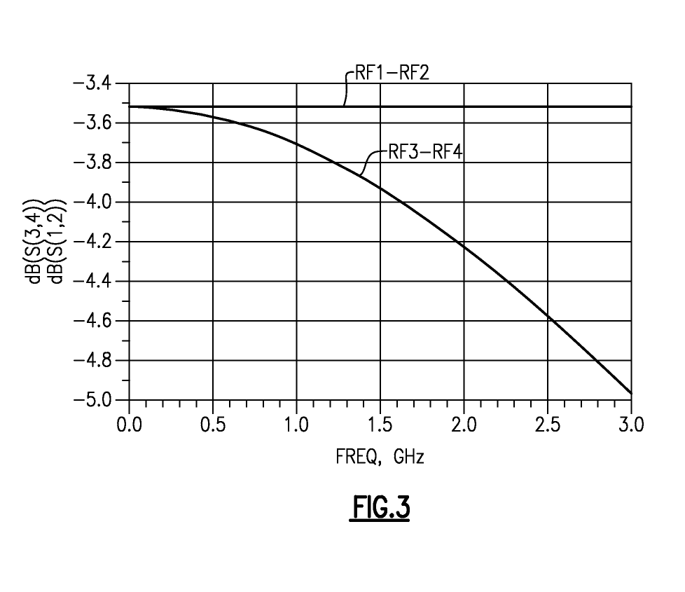

FIGS. 2A and 2B depict resistive signal paths, each having a characteristic impedance of 50 Ohms. The signal path in FIG. 2A is without parasitic capacitance to ground, and the signal path in FIG. 2B is with parasitic capacitance to ground. While various examples are described herein in the context of 50 Ohm impedance, it will be understood that other impedance values can also be implemented. It will also be understood that while the parasitic capacitance in the example of FIG. 2B is indicated as being 1 pF, other values of parasitic capacitance can exist.

FIG. 3 shows insertion loss plots associated with the example resistive signal paths of FIGS. 2A and 2B (without and with the parasitic capacitance). The plot indicated as RF1-RF2 is for the 50 Ohms path (without parasitic capacitance, as in FIG. 2A), and the plot indicated as RF3-RF4 is for the 50 Ohms path with parasitic capacitance to ground (as in FIG. 2B). As one can see, the latter is significantly worse, especially as frequency increases. Accordingly, parasitic capacitance can result in higher losses to a signal path such as a receive or transmit path associated with an antenna.

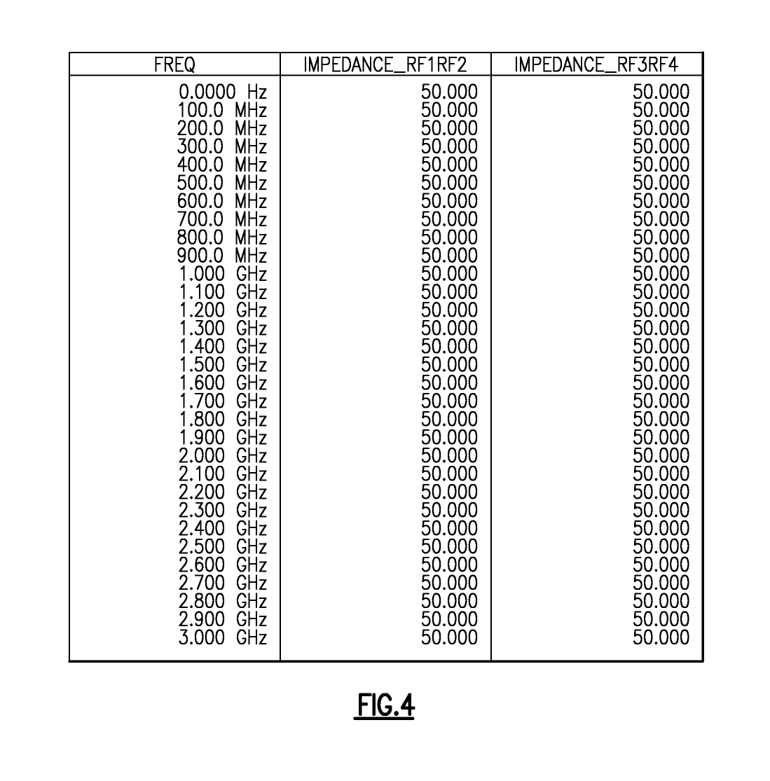

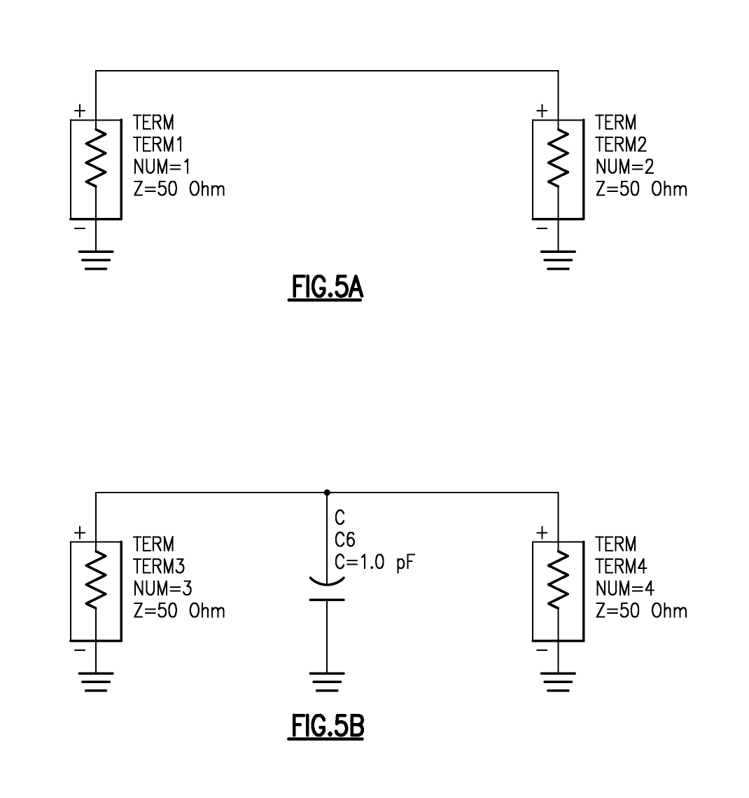

In the examples of FIGS. 2A and 2B, each signal path is has a characteristic impedance of 50 Ohms. FIG. 4 shows that such a characteristic impedance of each signal path can be approximately constant for a range of frequencies (e.g., from approximately DC to approximately 3.0 GHz). Thus, referring to FIGS. 2A, 2B, 3 and 4, one can see that although the impedance of the two paths can be the same, higher insertion losses occur in one path due to parasitic capacitance to ground.

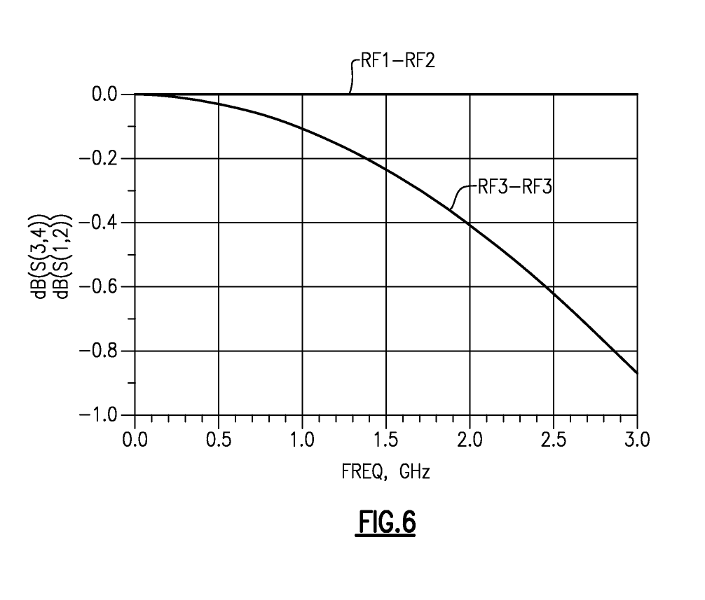

FIGS. 5A and 5B show ideal signal path, without and with parasitic capacitance to ground, respectively. While various examples are described herein in the context of 50 Ohm impedance, it will be understood that other impedance values can also be implemented. It will also be understood that while the parasitic capacitance in the example of FIG. 5B is indicated as being 1 pF, other values of parasitic capacitance can exist.

FIG. 6 shows insertion loss plots associated with the example ideal signal paths of FIGS. 5A and 5B (without and with the parasitic capacitance). The plot indicated as RF1-RF2 is for the ideal path (without parasitic capacitance, as in FIG. 5A), and the plot indicated as RF3-RF4 is for the ideal path with parasitic capacitance to ground (as in FIG. 5B). As one can see, the latter is significantly worse, especially as frequency increases. Although such ideal routing without resistive loss is generally not possible or practical, one can see that the parasitic capacitance losses to ground can be significant.

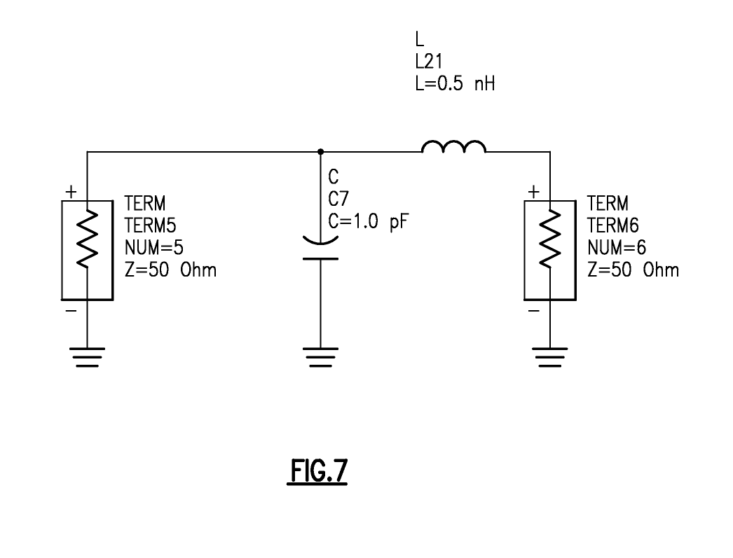

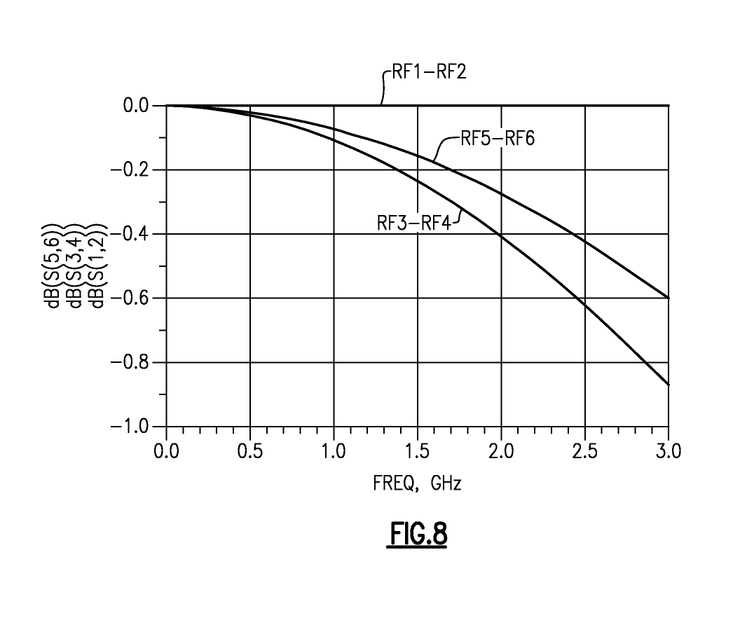

FIG. 7 shows an example configuration that can be implemented to reduce the parasitic capacitance effect associated with a signal routing path. A given routing path typically includes inductance; accordingly, such a routing path can be configured as a thinner line to decrease the parasitic capacitance effect. However, such a thinned line typically has an increase in resistance loss also. While the example of FIG. 7 is described in the context of 50 Ohm impedance, it will be understood that other impedance values can also be implemented. It will also be understood that while the inductance L associated with the example routing path of FIG. 7 is indicated as being 0.5 nH, other values of inductance can exist.

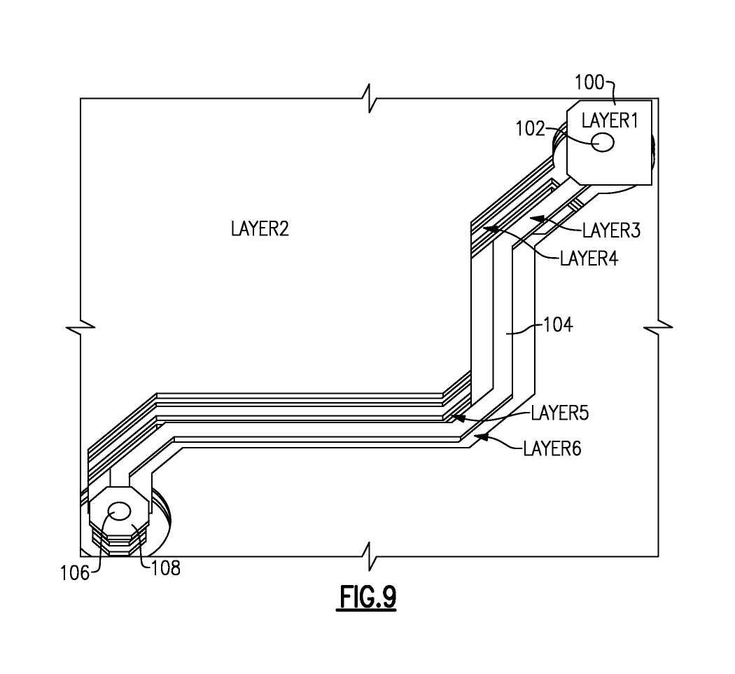

In FIG. 8, the insertion loss plots indicated as RF1-RF2 and RF3-RF4 are the same as those of FIGS. 5 and 6. The curve indicated as RF5-RF6 is for the example of FIG. 7 in which resistive loss exists due to the thinned routing line, but loss due to parasitic capacitance effect is reduced by the presence of inductance L. In the example shown, such a resistive loss can be more acceptable than the purely parasitic capacitance loss to ground.

In some embodiments, a signal path routing configuration as described herein can remove or reduce parasitic capacitance to ground effects. Such an improvement can be achieved by selectively removing, reducing, and/or configuring the presence of ground around one or more selected signal routing traces as much as a given module size allows.

It is noted that removing a grounding feature relative to a given RF signal route can benefit the RF signal route itself, and may not necessarily impact the coupling with another RF signal route. Accordingly, in some situations, removal of ground in any amount can be useful without hurting the overall coupling between RF routes.

It is also noted that an RF routing technique having one or more features as described herein can be implemented without interfering with the overall impedance of the routing path. Therefore, for the same mismatch losses, the insertion loss of Rx and/or Tx paths can be advantageously reduced.

Table 1 shows an overall reduction in insertion loss from example routing paths as described herein, and associated with an Rx+Tx chain to an antenna. Such insertion loss figures were tabulated at 1500 MHz, closer to a GPS band. At higher frequencies, the reduction in loss is expected to be greater, and at low bands the reduction in loss is expected to be lesser than the examples listed in Table 1. Therefore, a significant reduction in loss can be obtained utilizing one or more features as described herein.

TABLE 1
Loss Analysis at 1500 MHz

| RX Routing Path # | Loss Original (dB) | Loss Reduction (dB) |
|---|---|---|
| Path 1 | 0.015 | 0.014 |
| Path 2 | 0.481 | 0.462 |
| Path 3 | 0.041 | 0.028 |
| Path 4 | 0.029 | 0.028 |
| Path 5 | 0.033 | 0.016 |
| Path 6 | 0.083 | 0.047 |
| Path 7 | 0.332 | 0.312 |
| Path 8 | 0.089 | 0.062 |
| Tx Routing Path | 0.695 | 0.537 |
| Total | 1.798 | 1.506 |

| | |
|---|---|
| Loss Reduced (dB) | 0.292 |

FIG. 9 shows an example laminate substrate of a module with 6 layers. Such a 6-layered laminate can be utilized to accommodate advanced routing designs needed or desired for RF signal routes for Rx and Tx operations. Although various examples are described in the context of a 6-layer laminate substrate, it will be understood that one or more features of the present disclosure can also be implemented in laminate substrates having different numbers of layers. It will also be understood that one or more features of the present disclosure can also be implemented in any configuration involving a spatial arrangement between an RF signal path and one or more grounding features, whether or not such a spatial arrangement involves a layered structure.

In the example of FIG. 9, an RF signal route is shown to be implemented between nodes 100 and 108, both of which are on Layer 1. Starting from the first node 100 on Layer 1, the RF signal route goes to Layer 3 through Layer 2 using a first conductive via 102. The RF signal route continues on Layer 3 through a conductive trace 104 on Layer 3. The conductive trace 104 electrically connects the first conductive via 102 to a second conductive via 106. The second conductive via 106 electrically connects the conductive trace 104 to the second node 108 on Layer 1, to thereby complete the example RF signal route.

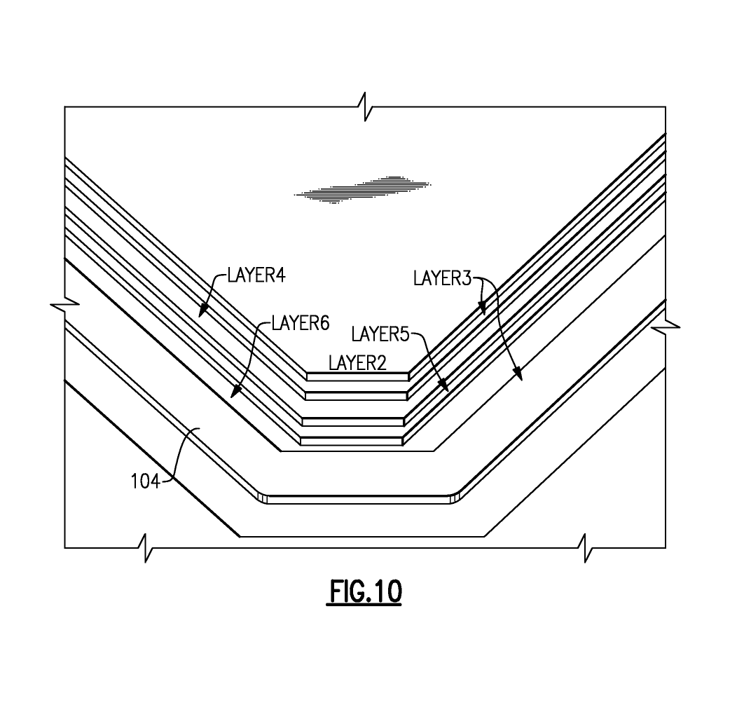

FIG. 10 shows a closer view of the example conductive trace 104 (on Layer 3) of FIG. 9. In the example of FIGS. 9 and 10, grounds at various layers can be removed or positioned sufficiently far away from the RF signal route so as to reduce the parasitic capacitance effects with respect to ground. For example, for the example shown in FIGS. 9 and 10, grounding features that overlap with the conductive trace 104 can be removed from Layers 1, 2, 4, and 5 so that the RF signal route on Layer 3 sees minimum or reduced capacitance to ground. In the example of FIGS. 9 and 10, Layer 6 is the chip ground and hence can be kept for electrical and mechanical stability.

In the example of FIGS. 9 and 10, grounds are removed from two layers above and two layers below the layer associated with the conductive trace. Such removal of grounds can involve a complete removal of a ground plane from a given layer, removal of ground plane or feature from locations on the given plane above or below the conductive trace 104 (e.g., removal of a grounding feature that overlaps with the conductive trace 104), or some combination thereof.

In some embodiments, such removal of ground or reduction of ground features can be implemented on at least one neighboring layer above a selected layer with the RF route conductive trace, and at least one neighboring layer below the selected layer. In the context of the example of FIGS. 9 and 10, grounds can be removed or reduced from Layers 2 and 4.

In some embodiments, and as described above, such removal of ground or reduction of ground features can be implemented on at least two neighboring layer above a selected layer with the RF route conductive trace, and at least two neighboring layer below the selected layer. In some embodiments where more layers are present, such removal of ground or reduction of ground features can be implemented on more than two neighboring layer above a selected layer with the RF route conductive trace, and more than two neighboring layer below the selected layer.

In some embodiments where an RF route conductive trace is on, for example, a top layer, at least one, at least two, or more than two layers below the top layer can have grounds removed or ground features reduced.

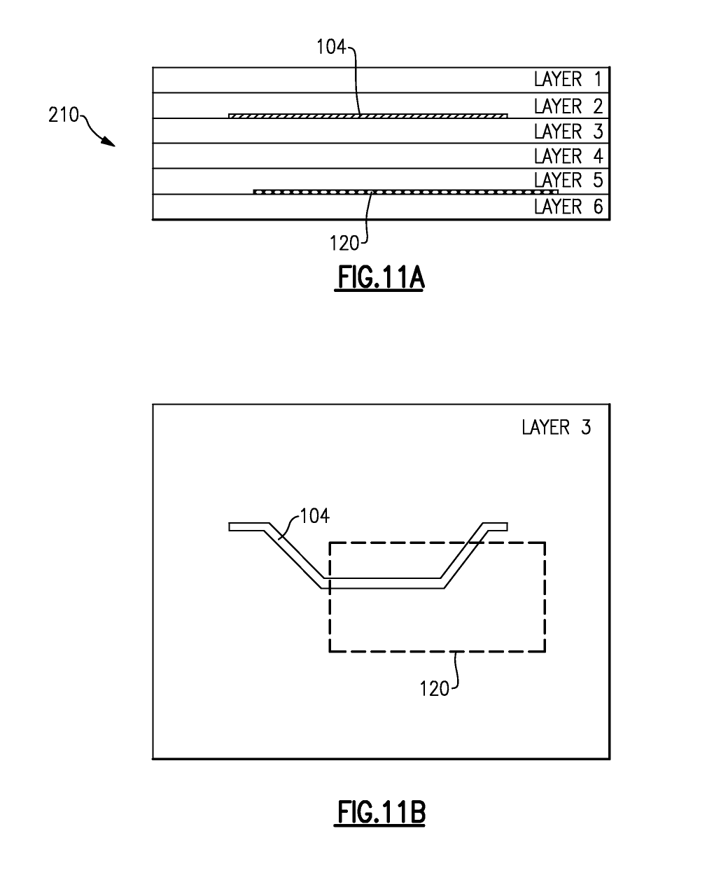

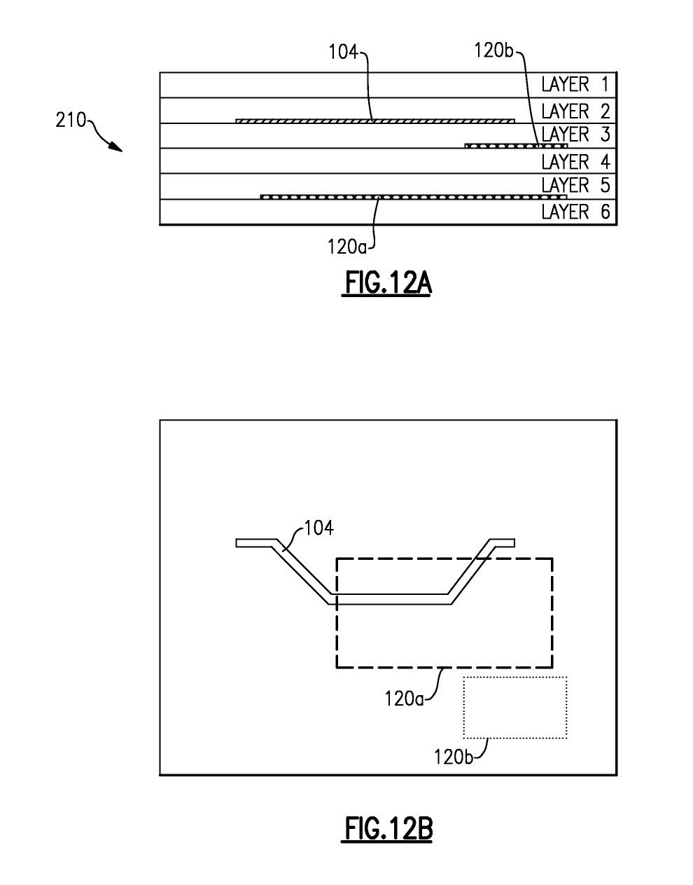

FIGS. 11 and 12 show more simplified views of laminate substrates that can be configured to provide reduced parasitic capacitance effects for conductive RF signal traces. As described herein, a conductive trace and one or more ground features can be configured to yield a desirable characteristic impedance for an RF signal being routed through the conductive trace. Such a characteristic impedance can be, for example, 50 Ohms.

It is noted that from a perspective of parasitic capacitance, reducing capacitive coupling between the conductive trace and the nearby ground features can generally reduce the parasitic capacitance. However, if too much ground is removed relative to the conductive trace, characteristic impedance can deviate away from a desired value such as 50 Ohms. Accordingly, in some embodiments, ground features can be removed or selectively positioned relative to the conductive trace to yield a reduced parasitic capacitance while approximately maintaining the desirable characteristic impedance.

FIGS. 11A (side view) and 11B (plan view) show that in some embodiments, a laminate substrate 210 can include a conductive trace 104 for routing of an RF signal. In the example shown, the conductive trace 104 is implemented on Layer 3 of a 6-layer laminate substrate. While the example conductive trace 104 is depicted as being similar to the example of FIGS. 9 and 10, it will be understood that other shapes can be implemented for the conductive trace 104. It will also be understood that the conductive trace 104 can be implemented on a layer other than Layer 3, and that the laminate substrate 210 can have other numbers of layers.

In some embodiments, the laminate substrate 210 can be substantially free of a ground feature that overlaps with the conductive trace 104, above the layer having the conductive layer (e.g., Layer 3) by at least one laminate layer, or by at least two laminate layers. Similarly, the laminate substrate 210 can be substantially free of a ground feature that overlaps with the conductive trace 104, below the layer having the conductive layer (e.g., Layer 3) by at least one laminate layer, or by at least two laminate layers. It will be understood that the upper overlapping-ground-free spacing may or may not be the same as the lower overlapping-ground-free spacing. For example, there may be a 3-layer spacing above the conductive trace, and a 2-layer spacing below the conductive trace.

In the example of FIGS. 11A and 11B, a ground feature 120 is shown to be implemented on Layer 6 so as to partially overlap with the conductive trace 104. Such an overlapping configuration can be acceptable due to sufficient spacing to yield reduced parasitic capacitance effect.

It is noted that capacitive coupling between a conductive trace and a ground feature can be an edge-coupling, a broadside-coupling, or some combination thereof. Typically, the broadside-coupling is a stronger coupling than the edge-coupling, and the overlap-free ground example described in reference to FIGS. 11A and 11B can address such broadside-coupling.

FIGS. 12A (side view) and 12B (plan view) show that in some embodiments, a ground feature can be positioned vertically closer to the conductive trace 104 than in the example of FIGS. 11A and 11B, if the ground feature does not overlap with the conductive trace 104. For example, in FIGS. 12A and 12B, the ground feature 120a (which overlaps with the conductive trace 104) can be similar to the ground feature 120 of FIGS. 11A and 11B. A ground feature 120b, which is shown to be implemented on Layer 4 (and thus separated vertically by one laminate layer), does not overlap with the conductive trace 104. Thus, if an example design specifies at least two layers of overlap-free ground above and below the conductive trace 104, the ground feature 120b can be acceptable due to its weaker coupling.

In the example of FIGS. 12A and 12B, the non-overlapping ground feature 120b can be implemented on a different layer, such as shown, or on the same layer as the layer on which the conductive trace 104 is implemented. Such a ground feature can be positioned laterally relative to the conductive trace 104 so as to allow maintenance of the desired characteristic impedance, as well as to reduce the parasitic capacitance effect.

It is noted that laminate substrates can have a number of different configuration in terms of, for example, number of layers, layer thickness, material, etc. It is further noted that a given laminate substrate can include a number of different conductive traces for routing of RF signals having different frequencies. It is further noted that characteristic impedances and parasitic capacitances associated with such conductive traces can also vary with frequency. Accordingly, it will be understood that a given assembly of a conductive trace and corresponding one or more ground features can be configured appropriately for a desired application, based on some or all of the foregoing design/operating parameters.

As described herein, removal of as much grounding features relative to a conductive trace can reduce the parasitic capacitance effect for that conductive trace. However, removal of too much ground relative to the conductive trace can result in unacceptable deviation in characteristic impedance for that conductive trace. Thus, in some embodiments, one or more ground features relative to a given conductive trace can be removed, modified, or any combination thereof, to reduce or substantially eliminate parasitic capacitance for the conductive trace, while maintaining the characteristic impedance of the conductive trace within a variation relative to a desired value. Such a desired value of characteristic impedance can be, for example, 50 Ohms. Such a variation can be, for example, less than 20%, 15%, 10%, 9%, 8%, 7%, 6%, 5%, 4%, 3%, 2%, or 1% of the desired characteristic impedance value. In the context of the example desired characteristic impedance value of 50 Ohms, such a variation can be less than 10 Ohms, 7.5 Ohms, 5 Ohms, 4.5 Ohms, 4.0 Ohms, 3.5 Ohms, 3.0 Ohms, 2.5 Ohms, 2.0 Ohms, 1.5 Ohms, 1.0 Ohm, or 0.5 Ohm.

FIG. 13 shows that in some embodiments, a packaging substrate 210 can include an assembly 110 of a conductive signal trace and one or more related ground features as described herein. As described herein, such an assembly can be configured to provide an effective signal path for routing of an RF signal. In some embodiments, the packaging substrate 210 can be configured to receive a plurality of components to facilitate formation of a package module.

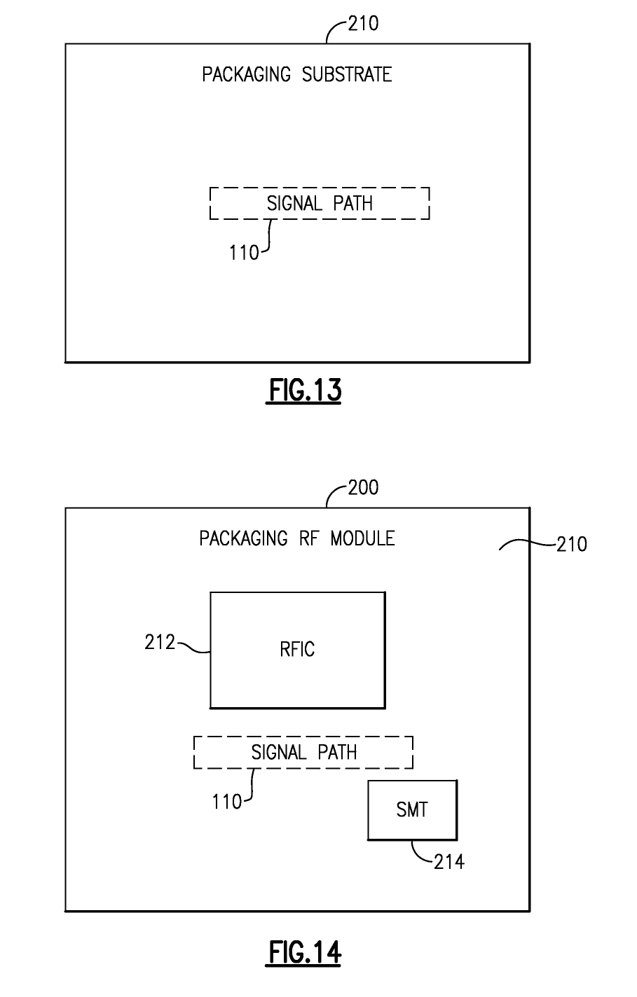

FIG. 14 shows that in some embodiments, one or more features of the present disclosure can be implemented in a packaged module 200. Such a module can include a packaging substrate 210 similar to the example of FIG. 13. In the example of FIG. 14, a plurality of components are shown to be mounted or implemented on the packaging substrate 210. For example, an RFIC device such as an RF die 212 can be mounted on the packaging substrate 210. In another example, a passive device such as an SMT device 214 can also be mounted on the packaging substrate 210.

In some embodiments, the packaged module 200 can be any module that is configured to route one or more RF signals. Such an RF module can be, for example, a power amplifier (PA) module, an antenna switch module (ASM), a low-noise amplifier (LNA) module, a front-end module (FEM), etc.

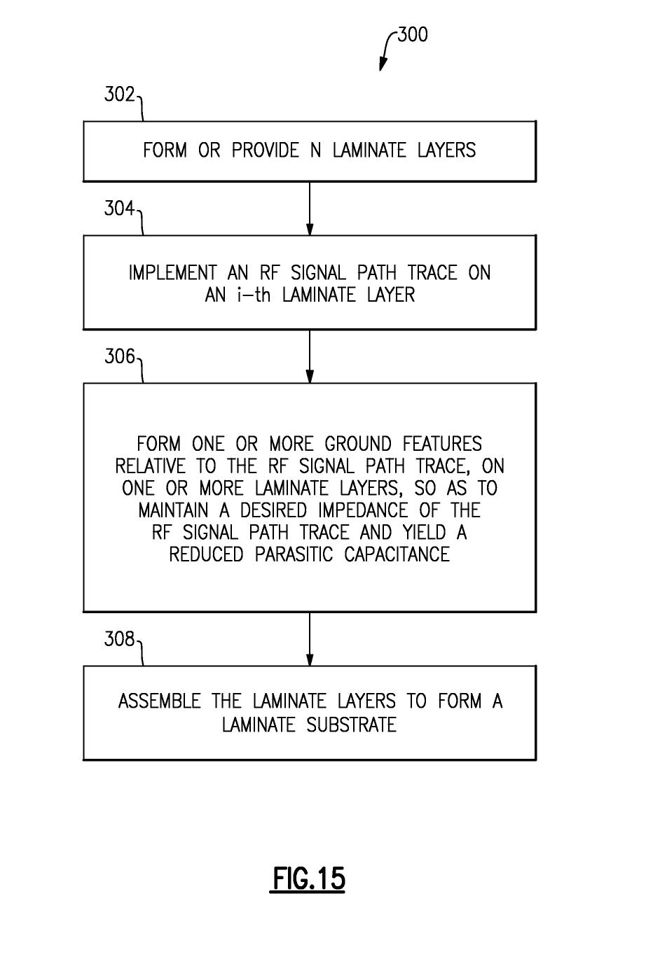

FIG. 15 shows a process 300 that can be implemented to fabricate a laminate substrate such as a packaging substrate. In block 302, N laminate layers can be formed or provided. In block 304, an RF signal path trace can be implemented on an i-th laminate layer. In block 306, one or more ground features can be formed relative to the RF signal path trace. Such ground feature(s) can be formed on one or more laminate layers so as to maintain a desired impedance of the RF signal path trace and yield a reduced parasitic capacitance. In block 308, the laminate layers can be assembled to form a laminate substrate.

In some embodiments, some or all of the foregoing fabrication process can be implemented on a panel having an array of units, with each unit corresponding to a packaging substrate for an individual module. Such units can be singulated before formation of the modules, after the formation of modules, or any combination thereof.

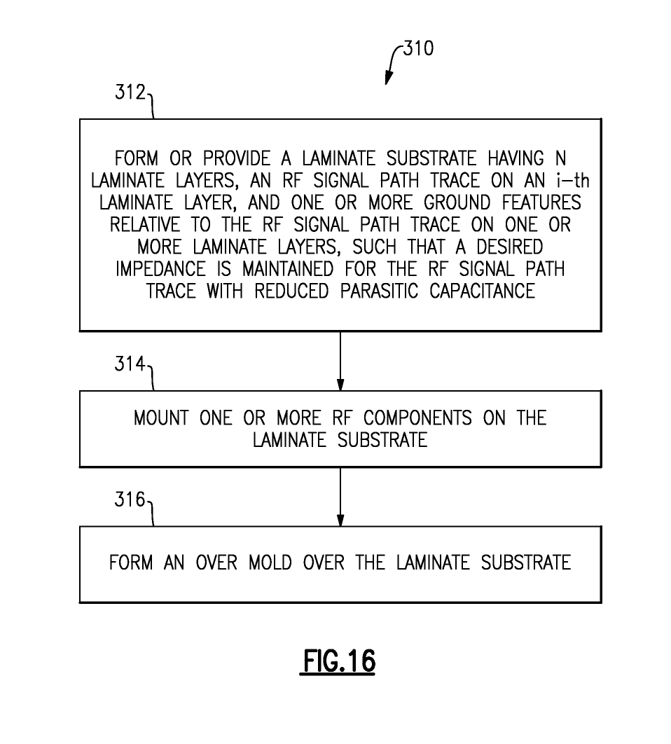

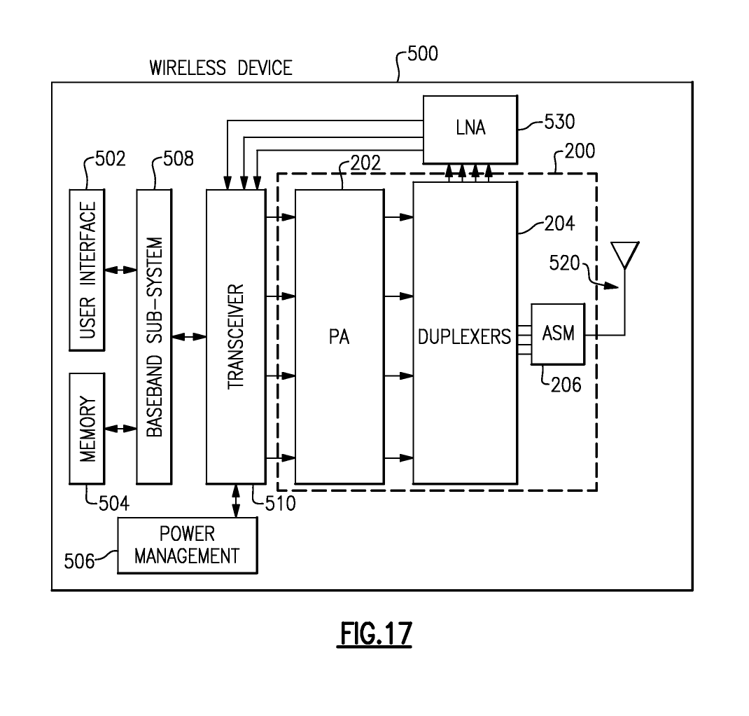

FIG. 16 shows a process 310 that can be implemented to fabricate a packaged module. In block 312, a laminate substrate having N laminate layers can be formed or provided. Such a laminate substrate can include an RF signal path trace on an i-th laminate layer, and one or more ground features relative to the RF signal path trace on one or more laminate layers, such that a desired impedance is maintained for the RF signal path trace with reduced parasitic capacitance. In some embodiments, the laminate substrate can be similar to the laminate substrate resulting from the process 300 of FIG. 15. In block 314, one or more RF components can be mounted on the laminate substrate. In block 316, an overmold can be formed over the laminate substrate.

In some implementations, an architecture, device and/or circuit having one or more features described herein can be included in an RF device such as a wireless device. Such an architecture, device and/or circuit can be implemented directly in the wireless device, in one or more modular forms as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc. Although described in the context of wireless devices, it will be understood that one or more features of the present disclosure can also be implemented in other RF systems such as base stations.

FIG. 17 depicts an example wireless device 500 having one or more advantageous features described herein. In some embodiments, such advantageous features can be implemented in, for example, a front-end (FE) module 200 having one or more features as described herein. In some embodiments, such an FEM can include more or less components than as indicated by the dashed box.

PAs 202 in the FEM 200 can receive their respective RF signals from a transceiver 510 that can be configured and operated to generate RF signals to be amplified and transmitted, and to process received signals. The transceiver 510 is shown to interact with a baseband sub-system 508 that is configured to provide conversion between data and/or voice signals suitable for a user and RF signals suitable for the transceiver 510. The transceiver 510 is also shown to be connected to a power management component 506 that is configured to manage power for the operation of the wireless device 500. Such power management can also control operations of the baseband sub-system 508 and other components of the wireless device 500.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example wireless device 500, the front-end module 200 can include an antenna switch module (ASM) 206. Such an ASM can provide signal routing control between an antenna 520 and a group of duplexers 204. Amplified RF signals to be transmitted can be routed from the PAs 202 to the antenna 520 through the duplexers 204 and the ASM 206. RF signals received through the antenna can be routed to respective LNA(s) 530 through the ASM 206, and the duplexers 204. Amplified signals from the LNA(s) 530 are shown to be routed to the transceiver 510.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A radio-frequency (RF) module comprising:
a plurality of components configured to facilitate processing of an RF signal; and
a packaging substrate on which the plurality of components are mounted, the packaging substrate having multiple layers and including an RF signal path implemented on a selected layer, each of at least one neighboring layer above the selected layer and at least one neighboring layer below the selected layer configured to be sufficiently free of a ground feature relative to the RF signal path to yield a reduced parasitic capacitance while substantially maintaining a desired impedance for the RF signal path.

2. The RF module of claim 1 wherein the RF module is a front-end module (FEM).

3. The RF module of claim 2 wherein the RF signal is an amplified transmit (Tx) signal.

4. The RF module of claim 2 wherein the RF signal is a received (Rx) signal.

5. The RF module of claim 1 wherein the packaging substrate includes a laminate substrate.

6. The RF module of claim 5 wherein the laminate substrate includes at least 6 layers.

7. The RF module of claim 1 wherein each of at least one neighboring layer above the selected layer and at least one neighboring layer below the selected layer is substantially free of a ground feature that would yield parasitic capacitance with the RF signal path on the selected layer.

8. The RF module of claim 7 wherein each of at least two neighboring layers above the selected layer and at least two neighboring layers below the selected layer is substantially free of a ground feature that would yield parasitic capacitance with the RF signal path on the selected layer.

9. The RF module of claim 8 wherein each of the at least two neighboring layers above the selected layer and at least two neighboring layers below the selected layer is substantially free of a ground feature that overlaps with the RF signal path on the selected layer.

10. The RF module of claim 1 wherein the desired impedance for the RF signal path includes an impedance value in a range of +/−10%, +/−5%, or +/−2% about an ideal impedance value.

11. The RF module of claim 10 wherein the ideal impedance value is approximately 50 Ohms.

12. The RF module of claim 1 wherein the plurality of components includes a semiconductor die having an RF integrated circuit (RFIC).

13. The RF module of claim 12 wherein the plurality of components further includes a surface-mount technology (SMT) device.

14. The RF module of claim 13 further comprising an overmold implemented over the packaging substrate to substantially encapsulate the plurality of components.

15. A wireless device comprising:
a transceiver configured to process a radio-frequency (RF) signal;
an RF module in communication with the transceiver, the RF module including a plurality of components configured to facilitate processing of the RF signal, the RF module further including a packaging substrate on which the plurality of components are mounted, the packaging substrate having multiple layers and including an RF signal path implemented on a selected layer, each of at least one neighboring layer above the selected layer and at least one neighboring layer below the selected layer configured to be sufficiently free of a ground feature relative to the RF signal path to yield a reduced parasitic capacitance while substantially maintaining a desired impedance for the RF signal path; and
an antenna in communication with the RF module, the antenna configured to facilitate transmission and/or reception of the RF signal.

16. The wireless device of claim 15 wherein the wireless device is a cellular phone.

17. A device for fabrication of packaged radio-frequency (RF) modules, the device comprising:
a substrate panel having an array of units, each unit configured to be a packaging substrate for an individual packaged RF module, the substrate panel including multiple layers; and
an RF signal path implemented on a selected layer of each unit of the substrate panel, each of at least one neighboring layer above the selected layer and at least one neighboring layer below the selected layer configured to be sufficiently free of a ground feature relative to the RF signal path to yield a reduced parasitic capacitance while substantially maintaining a desired impedance for the RF signal path.

18. The device of claim 17 wherein the substrate panel includes a laminate substrate panel.

19. The device of claim 18 wherein each of the at least one neighboring layer above the selected layer and at least one neighboring layer below the selected layer is substantially free of a ground feature that overlaps with the RF signal path on the selected layer.

20. The device of claim 19 wherein each of the selected layer, the at least one neighboring layer above the selected layer and the at least one neighboring layer below the selected layer includes a ground feature that is sufficiently displaced laterally from the RF signal path to contribute at least partially to the maintaining of the desired impedance.
